(19) United States
(12) Patent Application Publication
(10) Pub. No.: US 2026/0293180 A1
(43) Pub. Date: Sep. 24, 2026

(54) III-N DUAL GATE DEVICES

(71) Applicant: MONDE WIRELESS INC., Goleta, CA (US)

(72) Inventors: Matthew GUIDRY, Goleta, CA (US); Pawana SHRESTHA, Goleta, CA (US); Brian ROMANCZYK, Goleta, CA (US)

(21) Appl. No.: 19/476,022

(22) PCT Filed: Apr. 17, 2023
(86) PCT No.: PCT/US2023/018828

§ 371 Date: Oct. 16, 2025

(51) Int. Cl. H10D 30/47; H10D 30/01; H10D 62/824; H10D 64/60

(52) U.S. Cl. CPC H10D 30/4732; H10D 30/015; H10D 62/824; H10D 64/602

(57) ABSTRACT

III-N dual gate devices and methods of fabricating III-N dual gate devices. An example semiconductor device includes a III-N backbarrier, a III-N channel layer over the III-N backbarrier, and a two dimensional electron gas (2 DEG) channel in the III-N channel layer. The semiconductor device includes a source contact and a drain contact and, between the source contact and the drain contact, a first gate contact and a second gate contact. The semiconductor device includes, between the first and second gate contacts, an n+ GaN contact coupled to the III-N channel layer in a connection region.

### TECHNICAL FIELD

The current disclosure relates to semiconductor devices, and in particular to III-N devices with dual gates.

### BACKGROUND

Dual gate transistors and cascodes are two commonly used circuit elements in radio frequency (RF) circuits. A dual gate transistor is a type of field effect transistor (FET) that has two gates instead of one. Dual gate transistors can be useful in RF amplifiers, where they can provide high gain and low noise.

Cascodes, on the other hand, are a type of circuit that combines two or more transistors to create a high gain, low noise amplifier. In a cascode circuit, two transistors are connected in series so that the drain of the first transistor is connected to the source of the second transistor. This increases the maximum stable gain, which is useful for many RF circuits.

Both dual gate transistors and cascodes are commonly used in RF circuits because of their ability to provide high gain, low noise amplification. Dual gate transistors and cascodes are often used in low noise amplifiers, mixers, frequency synthesizers, RF amplifiers, mixers, and other high frequency circuits. By combining these circuit elements with other passive components, such as inductors and capacitors, engineers can design complex RF circuits that can be used in a variety of applications, including wireless communications, radar systems, and more.

### SUMMARY

In a first aspect of this disclosure, a semiconductor device includes a III-N backbarrier, a III-N channel layer over the III-N backbarrier, and a two dimensional electron gas (2 DEG) channel in the III-N channel layer. The semiconductor device includes a source contact and a drain contact and, between the source contact and the drain contact, a first gate contact and a second gate contact. The semiconductor device includes, between the first and second gate contacts, an n+ GaN contact coupled to the III-N channel layer in a connection region.

### DESCRIPTION OF DRAWINGS

FIG. 1 is a circuit diagram of an example dual gate transistor;

FIG. 2 is a cross-sectional view illustrating an example configuration of the dual gate transistor;

FIG. 3 is a cross-sectional view of the dual gate transistor showing an example having an ohmic metal on top of the n+ GaN contact in the connection region;

FIG. 4 is a cross-sectional view of the dual gate transistor in an example lacking the n+ GaN contact but including the ohmic metal;

FIG. 5 is a cross-sectional view of the dual gate transistor in an example where the first and second gate contacts and are recessed to different depths;

FIG. 6 is a cross-sectional view of the dual gate transistor in an example where an access region is recessed to a different depth;

FIG. 7 is a cross-sectional view of the dual gate transistor in an example having one or more etch stop layers;

FIG. 8 is a cross-sectional view of the dual gate transistor in an example where the first gate contact 116 is recessed through both etch stop layers;

FIG. 9 is a cross-sectional view of the dual gate transistor in an example with a single etch stop layer;

FIG. 10 is a cross-sectional view of the dual gate transistor in an example with a “raised” n+ GaN contact;

FIG. 11 is a top view of the dual gate transistor in a configuration where the gates have different widths;

FIG. 12 is a top view of the dual gate transistor in an example with a gate having non-conducting regions;

FIG. 13 is a cross-sectional view of an example dual gate transistor made with Ga-polar GaN;

FIG. 14 is a cross-sectional view of the transistor in an example where the n+ GaN contact extends through the barrier layer; and FIG. 15 is a flow diagram of an example method 300 for fabricating a dual gate HEMT with an n+ GaN contact.

### DETAILED DESCRIPTION

This document describes dual gate transistors formed from a III-N materials system. In some examples, a dual gate transistor includes a substrate, a buffer layer, a III-N backbarrier, a III-N channel layer, and a two dimensional electron gas (2 DEG) channel in the III-N channel layer. The dual gate transistor includes a source contact and a drain contact and, between the source contact and the drain contact, a first gate contact and a second gate contact. The dual gate transistor includes, between the first and second gate contacts, a III-N contact coupled to the III-N channel layer in a connection region. The III-N contact can include highly doped n+ GaN.

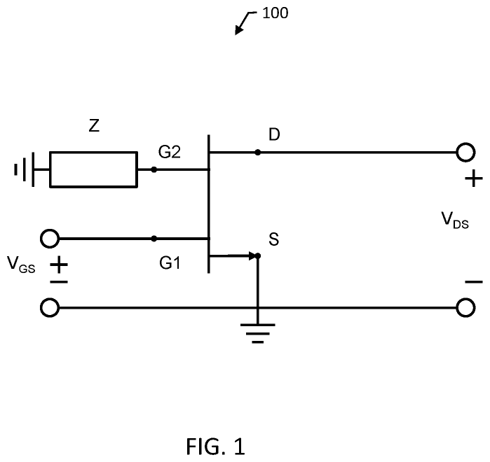

FIG. 1 is a circuit diagram of an example dual gate transistor 100. The transistor includes source(S) and drain (D) contacts, first and second gate contacts (G1 and G2), and an impedance Z. The dual gate transistor 100 is formed from a III-N materials system.

Compared to some conventional transistors, the dual gate transistor 100 can provide one or more of the following advantages.
Higher gain per stage:
   Reduced number of amplifier stages (reduced wafer area, more compact system, lower power consumption)
   Potentially higher power-added efficiency, so long as the added resistance of the dual-gate does not excessively increase the knee voltage
Higher output power density
   Higher breakdown voltage could provide higher output power density for power amplifier applications
Higher switch performance
   A dual-gate device may have a smaller off-state capacitance (C_{off}). If the on resistance (Rₒₙ) does not increase much, it may have a small C_{off}*Rₒₙ product, and higher switch performance

The dual gate transistor may be suitable for use in one or more of the following applications:
Power amplifiers
Variable gain amplifiers
   The bias on G2 can be used to adjust the gain over a wide range for signal leveling amplifiers or beamformers
Low noise amplifiers
RF switches
Front-end modules including transmit-receive modules

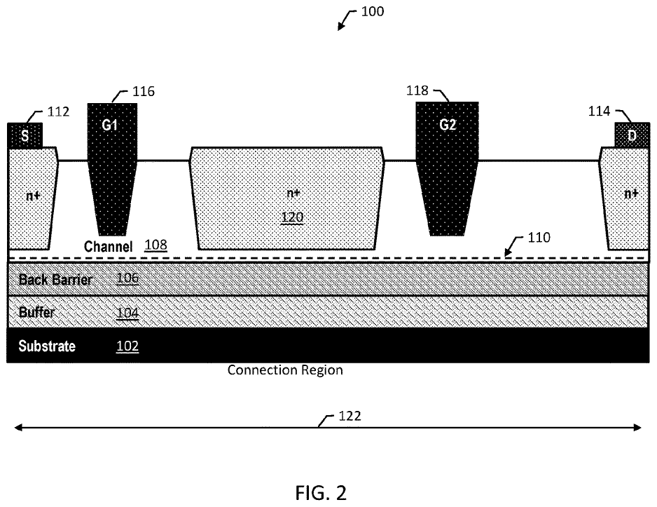

FIG. 2 is a cross-sectional view illustrating an example configuration of the dual gate transistor 100. The transistor 100, which is configured as a high electron mobility transistor (HEMT), includes a substrate layer 102, a buffer layer 104, and a III-N back barrier layer 106. The substrate layer 102 can be made of, for example silicon, silicon carbide, sapphire, AIN, or GaN. The transistor 100 includes a III-N channel layer 108 over the III-N back barrier layer 106. As used herein, the terms III-Nitride or III-N materials, layers, devices, etc., refer to a material or device comprised of a compound semiconductor material according to the stoichiometric formula ScᵥB_{w}AlₓIn_{y}Ga_{z}Nₐ(D)_{b}, where v+w+x+y+z is about 1, 0≤v≤1, 0≤w≤1, 0≤x≤1, 0≤y≤1, 0≤z≤1, a+b is about 1, 0.9≤a≤1, 0≤b<0.1, and (D) is any group-V element other than nitrogen.

The buffer layer 104 can, for example, be formed of or include GaN, and is configured to enable the growth of high quality III-N active device layers thereover. The back barrier layer 106 can, for example, be formed of or include AlₓGa₁₋ₓN. The bandgap of the back barrier layer 106 can be larger than that of the buffer layer 104. The III-N channel layer 108 can, for example, be GaN. The III-N channel layer 108 has a different composition than the back barrier layer 106, e.g., so that the bandgap of the back barrier layer 106 is larger than that of the III-N channel layer 108.

The thicknesses of layers 108 and 106 are selected such that a two-dimensional electron gas (2 DEG) channel 110 (indicated by the dashed line in FIG. 2) is induced in the III-N channel layer 108 adjacent to the interface between the back barrier layer 106 and III-N channel layer 108. The 2 DEG channel 110 is a layer of electrons that is formed at the interface between two semiconductor materials with different bandgaps.

The transistor 100 includes a source contact 112 coupled to the III-N channel layer 108 and a drain contact 114 coupled to the III-N channel layer 108 and spaced apart from the source contact 112 along a length 122 of the transistor 100. The transistor 100 includes, between the source contact 112 and the drain contact 114, a first gate contact 116 above the III-N channel layer 108 and a second gate contact 118 above the III-N channel layer 108. The contacts 112 and 114 are electrically connected to the 2 DEG channel 110. Voltages are applied to the gate contacts 116 and 118 relative to the potential at source contact 112 modulate the charge in the 2 DEG channel 110. As used herein, two or more contacts or other items such as conductive layers or components are said to be “electrically connected” or “coupled” if they are connected by a material which is sufficiently conducting to ensure that the electric potential at each of the contacts or other items is intended to be the same, i.e., is about the same, at all times under typical bias conditions.

In general, any suitable materials can be used to form the contacts 112, 114, 116, and 118. As shown in the example of FIG. 2, the source and drain contacts 112 and 114 are formed of an ohmic metal over a III-N material. For the source and drain contacts 112 and 114, metals with good electrical conductivity, low contact resistance, and high thermal stability are typically used. Commonly used metals for III-N transistors include nickel (Ni), gold (Au), aluminum (Al), titanium (Ti), and platinum (Pt), as well as alloys such as titanium-aluminum (Ti/Al) and nickel-gold (Ni/Au). The specific choice of contact material may depend on the device requirements, such as the desired operating temperature range, the type of III-N material used, and the specific device architecture.

For the gate contacts 116 and 118, the transistor 100 may include a material with high work function to ensure that the gate voltage can effectively control the flow of carriers in the channel 108, as well as potentially having favorable manufacturing properties such as surface adhesion and etch selectivity. Typically, metals such as platinum (Pt), palladium (Pd), or alloys such as nickel-gold (Ni/Au) or titanium-gold (Ti/Au), titanium-nitride (TiN), are used. Low work function metals such as Ti or Al, or alloys of metals, can also be used to form a gate contact when an additional insulating layer is placed between the III-N layer and gate metal. Examples of insulating layers include silicon nitride, aluminum oxide, silicon oxide, hafnium oxide, or aluminum silicon oxide. Stacks of, e.g., Ni/Au or Ti/Au may be used.

The transistor 100 includes an n+ GaN contact 120 coupled to the III-N channel layer 108 in a connection region between the first gate contact 116 and the second gate contact 118. n+ GaN refers to a type of Gallium Nitride (GaN) semiconductor material that has been heavily doped with impurities (e.g., silicon or germanium) to increase its electrical conductivity. In this context, the “n” refers to the type of doping, which introduces electrons into the crystal lattice structure of the GaN material, creating an excess of negative charge carriers. The “+” sign indicates that the material is heavily doped, meaning that a high concentration of impurities has been intentionally added to the material to increase its conductivity. n+ GaN is a key material used in the development of high-power, high-frequency electronic devices such as power amplifiers and radio frequency (RF) switches. Its unique material properties, including its high electron mobility, high thermal conductivity, and wide bandgap, make it well-suited for use in these applications.

As used in this document, n+ GaN refers to GaN that has been sufficiently doped to make it suitable for applications that require high-speed electronic devices, such as power electronics and high-frequency transistors. The doping concentration can range from, e.g., 10¹⁸ to 10²⁰ cm⁻³. The actual doping concentration achievable in a particular configuration depends on a number of factors, such as the purity of the starting material, the doping technique, and the growth conditions. Therefore, the precise doping concentration in n+ GaN may vary depending on the specific processing methods and conditions used to fabricate the material.

In operation of the transistor 100, when a voltage is applied to the first gate contact 116 relative to the voltage at source contact 112, it creates an electric field that modulates the density of electrons in the 2 DEG channel 110 in the vicinity of gate contact 116. This, in turn, modulates the conductivity of the channel 108 in the vicinity of gate contact 116, providing variable current flow.

The second gate contact 118 can be used to control the output current and impedance at the drain contact 114 of the transistor 100. By applying a voltage and impedance to the second gate contact 118 the profile of electrons in the 2 DEG channel 110 can be further modulated in a way that increases the output impedance at drain contact 114. This can increase the voltage gain from gate contact 116 to drain contact 114 with source contact 112 as a common terminal relative to a transistor which did not have the second gate contact 118.

One of the advantages of the dual-gate configuration is that it provides more gain compared to single-gate HEMTs. The two gate contacts 116 and 118 can be biased independently, allowing for greater control over the device's characteristics. The transistor 100 can be used in high-frequency amplifiers, mixers, and other RF applications where high linearity and low noise are important.

In some examples, the buffer layer 104, back barrier layer 106, and channel layer 108 are N-polar III-N layers. Then, the III-N channel layer 108 is on an N-face of the back barrier layer 106. The n+ GaN contact 120 can also be formed as N-polar GaN. Optionally, the substrate 102 can be removed after forming the other layers 104, 106, and 108, such that substrate 102 is not included in the final transistor structure. Furthermore, some or all of any III-N layers that underlie the back barrier layer 106 (e.g., the buffer layer 104) can also optionally be removed after formation of the back barrier 106 and the III-N channel layer 108.

The n+ GaN contact 120 in the connection region can enhance the conductivity of the transistor 100. The presence of the n+ GaN contact 120 may be especially useful in cases where N-polar n+ GaN is used for the contact 120 as the n+ GaN in the connection region increases conductivity of the 2 DEG channel 110, providing a high conductivity current path through the connection region without additional ohmic contact resistances.

N-polar GaN is a type of GaN crystal growth orientation that refers to a particular surface of the GaN crystal where nitrogen (N) atoms are predominantly located. In N-polar GaN, the (000-1) crystal plane is the dominant surface, while the gallium (Ga) atoms are located primarily on the (0001) plane. Compared to other GaN growth orientations, such as the commonly used c-plane Ga-polar GaN (0001), N-polar GaN has a number of unique properties. For example, the inverted polarization-induced electric field allows for N-polar GaN transistors to be formed using heterostructures where the 2 deg is formed above the charge-inducing barrier layer proving improved gate control (higher gain) and lower contact resistance (higher efficiency). N-polar GaN transistors also typically exhibit higher electron mobility at high charge densities.

In this case, for the dual gate transistor 100, the N-polar GaN allows for a high-conductivity continuous 2 DEG channel 110 between the first gate contact 116 and second gate contact 118, which can result in a relatively lower RON for the transistor 100 compared to some other devices. (For example, in cases where Ga-polar is used for a contact in the connection region, the 2 DEG channel 110 would likely be broken, resulting in higher resistance.) Moreover, the low resistance per unit length of the connection region enables the first and second gate contacts 116 and 118 to be placed further apart, which can make the transistor 100 easier to fabricate.

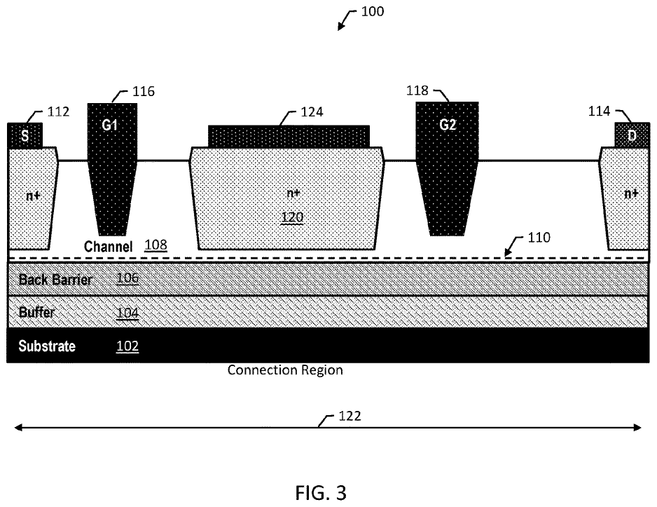

FIG. 3 is a cross-sectional view of the dual gate transistor 100 showing an example having an ohmic metal 124 on top of the n+ GaN contact 120 in the connection region. The ohmic metal 124 can be formed of any appropriate type of material.

Typically, ohmic metal includes a material that exhibits a linear current-voltage (I-V) behavior under low bias voltage, meaning that the current flowing through the metal-semiconductor interface is directly proportional to the applied voltage. Some examples of metals commonly used as ohmic contacts in III-N transistors include titanium (Ti), aluminum (Al), platinum (Pt), palladium (Pd), nickel (Ni), gold (Au), and tungsten (W). In addition to pure metals, metal alloys, such as nickel-gold (Ni/Au) and titanium-aluminum (Ti/Al), are also commonly used as ohmic contacts in III-N devices.

The presence of the ohmic metal 124 results in current in the connection region flowing in three different regions: within the 2 DEG channel 110, within the n+ GaN contact 120, and within the ohmic metal 124. The current through the n+ GaN contact 120 and the ohmic metal 124 incurs a contact resistance penalty, but each path will add to the total conductivity of the connection region.

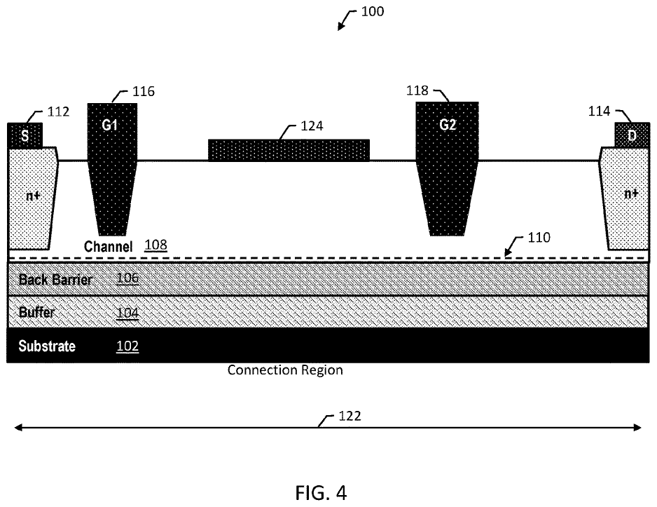

FIG. 4 is a cross-sectional view of the dual gate transistor 100 in an example lacking the n+ GaN contact but including the ohmic metal 124. Including the ohmic metal 124 on the surface of the III-N channel 108 in the connection region could provide a benefit to conductivity although the benefit is likely smaller compared to configurations with the n+ GaN contact.

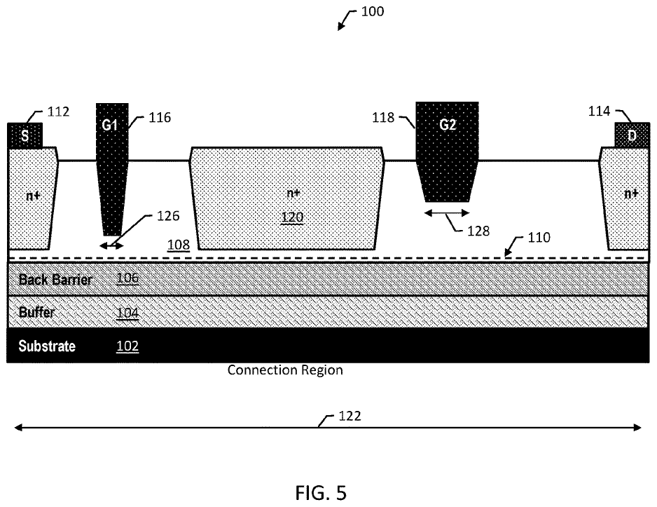

FIG. 5 is a cross-sectional view of the dual gate transistor 100 in an example where the first and second gate contacts 116 and 118 are recessed to different depths in the III-N channel layer 108. The first gate contact 116 is recessed to a first depth, the second gate contact 118 is recessed to a second depth, and, in the example shown the first depth is greater than the second depth.

This configuration can be useful for stability and power. With the first gate contact 116 being recessed deeper, the threshold voltage of the second gate (V_{T2}) may be more negative that of the first gate (V_{T1}) which may be advantageous in some circuits.

In some examples, the second gate contact 118 has a length 128 greater than a length 126 of the first gate contact 116. This can be useful, e.g., to increase the gain of first gate and increase the breakdown voltage of the second gate.

A possible drawback of configuring the transistor 100 as shown in FIG. 5 is that two etch depths may be needed, which can increase the fabrication complexity. This configuration, however, may have one or more of the following advantages:
Lower gain associated with the second gate contact 118 reduces oscillation
More negative V_{T2} increases the voltage held by the first gate contact 116, increasing the total breakdown voltage of the transistor 100 (and therefore power density)
Thicker channel increases the current for the second gate contact 118 when V_{G2}=0V, which can remove need for a bias network for the second gate contact 118

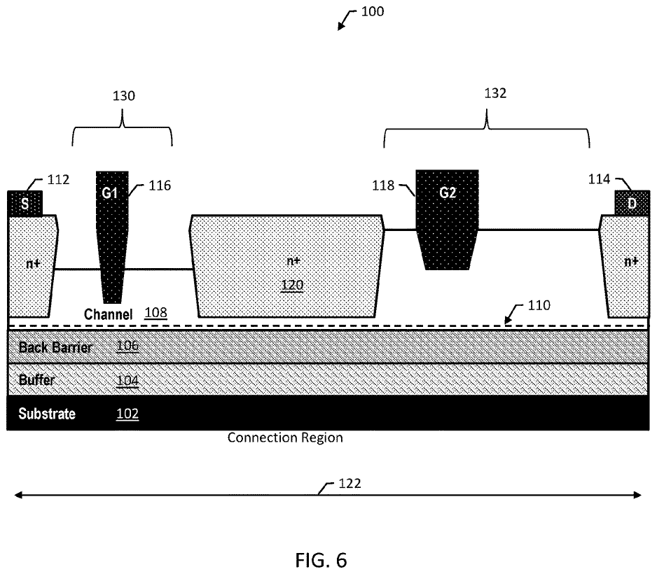

FIG. 6 is a cross-sectional view of the dual gate transistor 100 in an example where the access region is recessed to different depths. As shown in this example, a first access region 130 between the source contact 112 and the n+ GaN contact 120 is recessed to a first access region depth, a second access region 132 between the drain contact 114 and the n+ GaN contact 120 is recessed to a second access region depth, and the first access region depth is greater than the second access region depth.

Having the access region recessed to different depths can be useful, e.g., for gain and stability and can provide one or more of the following advantages:
The first gate contact 116 does not need to hold as much voltage between it and the 2 DEG towards the drain, so it does not need as much GaN cap/channel thickness for dispersion control. It can be thinned to reduce the capacitance and increase gain.
The first gate contact 116 can be recessed further than the second gate contact 118 (as shown in FIG. 5) so that V_{T2} is more negative than V_{T1}
   This will typically coincide with L_{G2} longer than L_{G1}
It may be convenient, and reduce the number of process steps, to have the access region etch around the first gate contact 116 to coincide with the gate recess etch for the second gate contact 118.

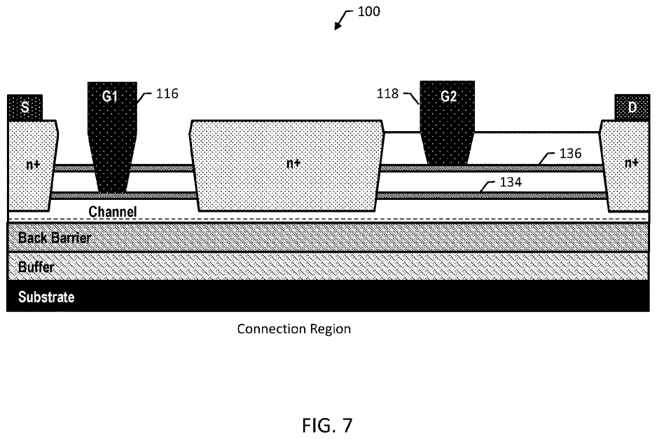

FIG. 7 is a cross-sectional view of the dual gate transistor 100 in an example having one or more etch stop layers. As shown in FIG. 7, the transistor 100 includes two etch stop layers 134 and 136. The first gate contact 116 is recessed to the first etch stop layer 134 and the second gate contact 118 is recessed to the second etch stop layer 136. The etch stop layers can be formed using materials with composition that is different from the layer being etched, for example AlGaN, InAlN, or p+ GaN.

Etch stop layers can be used to precisely control etch depths. It may also be convenient to use the same etch stop layer to establish the access region depth around the first gate contact 116 and the gate recess depth for the second gate contact 118, e.g., as shown in FIG. 7.

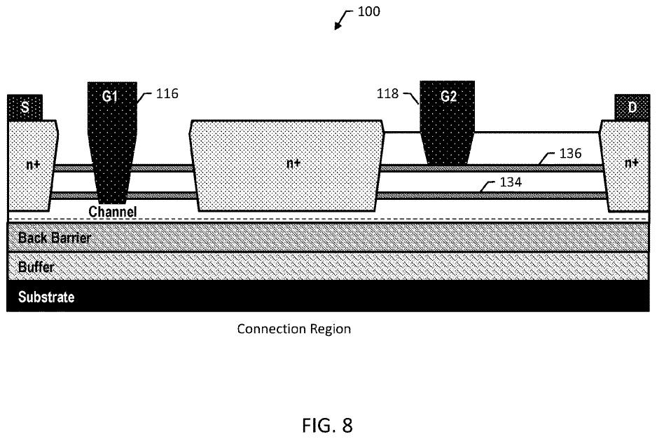

FIG. 8 is a cross-sectional view of the dual gate transistor 100 in an example where the first gate contact 116 is recessed through both etch stop layers 134 and 136 and past the first etch stop layer 134. This can be useful, e.g., to bring the first gate contact 116 closer to the channel and increase the transconductance and gain. The second gate contact 118 could be recessed through the second etch stop layer 136 in a similar manner.

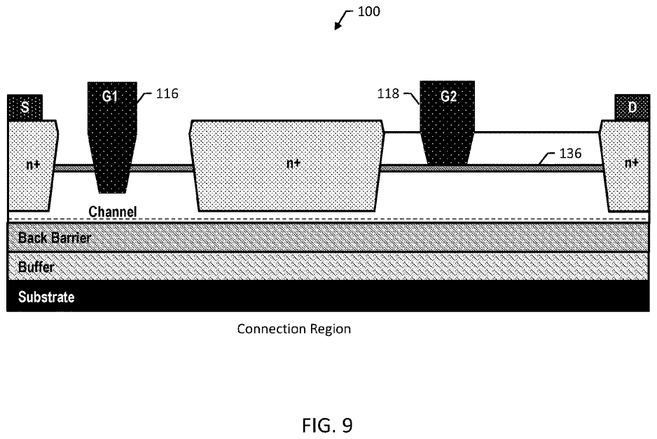

FIG. 9 is a cross-sectional view of the dual gate transistor 100 in an example with a single etch stop layer 136. The single etch stop layer 136 can be useful, e.g., to simplify the epitaxy and formation of the n+ contacts to 2 deg. The single etch stop layer 136 can be used to define a recess depth for the access region around the first gate contact 116 and the second gate contact 118. The first gate contact 116 can be recessed past the etch stop layer to increase the transconductance while gaining some dispersion control.

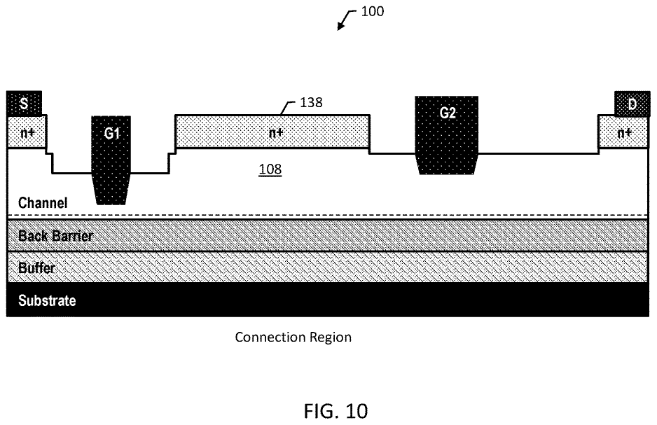

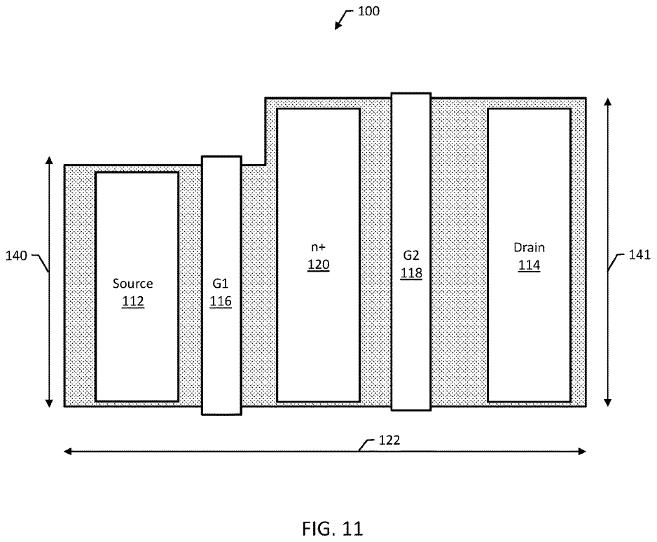

FIG. 10 is a cross-sectional view of the dual gate transistor 100 in an example with a “raised” n+ GaN contact 138. In the examples shown in FIGS. 2-9, the n+ GaN contact 120 is illustrated as being re-grown off of an etched portion of the III-N channel layer 108 or ion-implanted into III-N channel layer 108. In the example shown in FIG. 10, the n+ GaN contact 138 is on a top surface of the III-N channel layer 108. The n+ GaN contact 138 can be grown in-situ, regrown n+, or formed by implantation. The other features from FIGS. 2-9, such as different gate depths, can also be present with the “raised” n+ GaN contact 138.

FIG. 11 is a top view of the dual gate transistor 100 in a configuration where the gates 116 and 118 have different widths. In general, some or all of the contacts 112, 114, 116, 118, and 120 can have varying widths. For example, the first gate contact 116 can have a first gate width 140, the second gate contact 118 can have a second gate width 141, and the second gate width 142 can be wider than the first gate width 141. The source contact 112 may have the same width as the first gate contact 116, and the drain contact 114 and the n+ GaN contact 120 may have the same width as the second gate contact 118.

Since the current is the same through the two cells, making the width of the second gate contact 118 wider can prevent it from acting as a current choke. This could allow, e.g., the second gate contact 118 to be direct current (DC) DC grounded to the source potential rather than requiring a DC bias and bypass capacitor. In some cases, there will be a current spreading resistance going between the two cells due to the step change in active width.

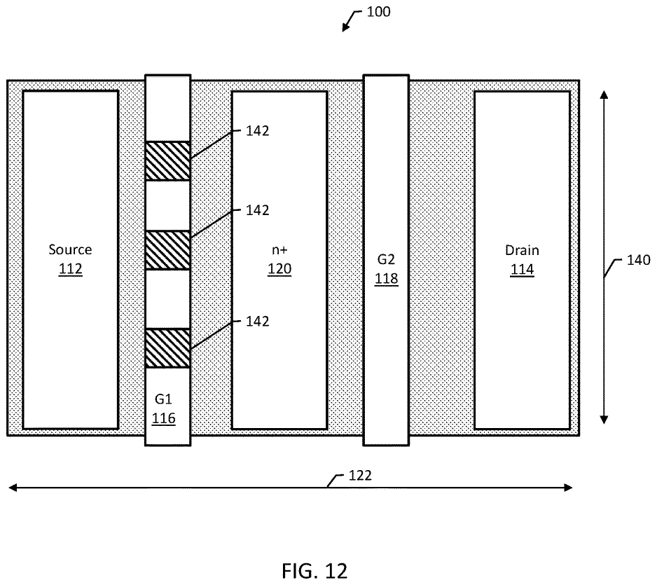

FIG. 12 is a top view of the dual gate transistor 100 in an example with a gate having non-conducting regions. As shown in FIG. 12, the first gate contact 116 includes a number of non-conducting regions 142 along the width of the first gate contact 116. The non-conducting regions 142 are alternating with conducting regions. The non-conducting regions 142 can be rendered non-conducting, e.g., by implant isolation or etching. Thus, effectively, the current-carrying gate width of the 2 DEG under the first gate contact 116 is less than the current-carrying gate width of the 2 DEG under the second gate contact 118. Compared to the example shown in FIG. 11, spreading resistance issues can be mitigated because current flow is more uniform.

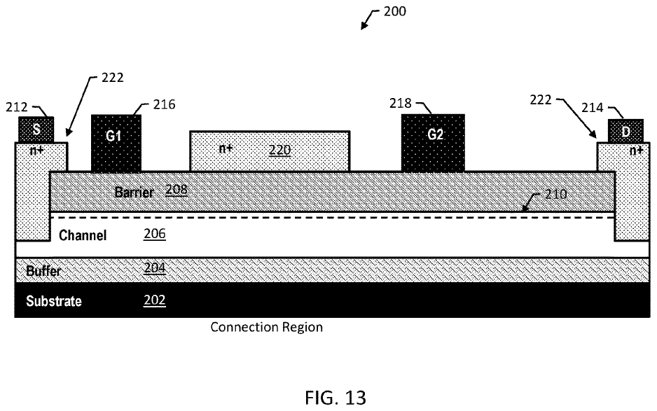

FIG. 13 is a cross-sectional view of an example dual gate transistor 200 made with Ga-polar GaN. The transistor 200 includes a substrate 202, a buffer layer 204, a III-N channel layer 206, and a III-N barrier layer 208 over the III-N channel layer 206. The III-N barrier layer 208 and the III-N channel layer 206 are configured to form a 2 DEG channel 210 in the III-N channel layer 206. The buffer layer may also comprise a backbarrier to confine charge in the channel, either by nature of its composition, or inclusion of specific layers adjacent to the channel layer 206.

The transistor 200 includes a source contact 212 coupled to the III-N channel layer 206 and a drain contact 214 coupled to the channel layer 206 and spaced apart from the source contact 212 along a length of the transistor 200. The transistor 200 includes, between the source contact 212 and the drain contact 214, first and second gate contacts 216 and 218 coupled to the barrier layer 208.

The transistor 200 includes an n+ GaN contact 220 coupled to the barrier layer 208 in a connection region between the first gate contact 216 and the second gate contact 218. The n+ GaN contact 220 is made from Ga-polar GaN.

For Ga-polar GaN regrown contacts, some overhang 222 can be included to help ensure a 2 DEG channel 210 is present adjacent to the buried n+ GaN. The overhang 222 is likely to enhance the charge concentration in the 2 DEG channel 210 in the connection region.

The Ga-polar transistor 200 may not work as well as examples that use N-polar GaN, because the n+ GaN contact 220 will not participate significantly in the conduction in the connection region without it being recessed. While the n+ GaN contact 220 will enhance the conductivity of the 2 DEG in the channel, it will not do so to the same extent that it will in N-polar GaN structures.

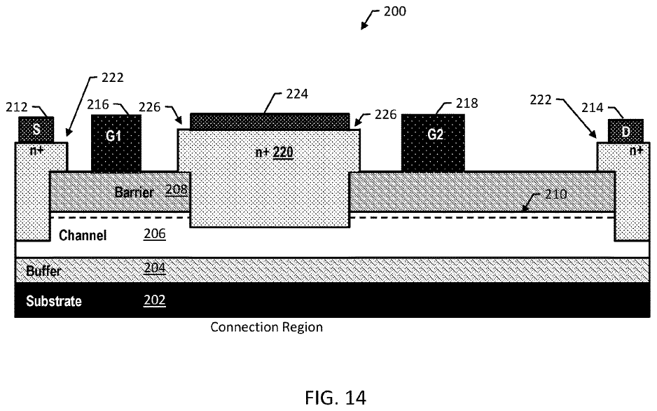

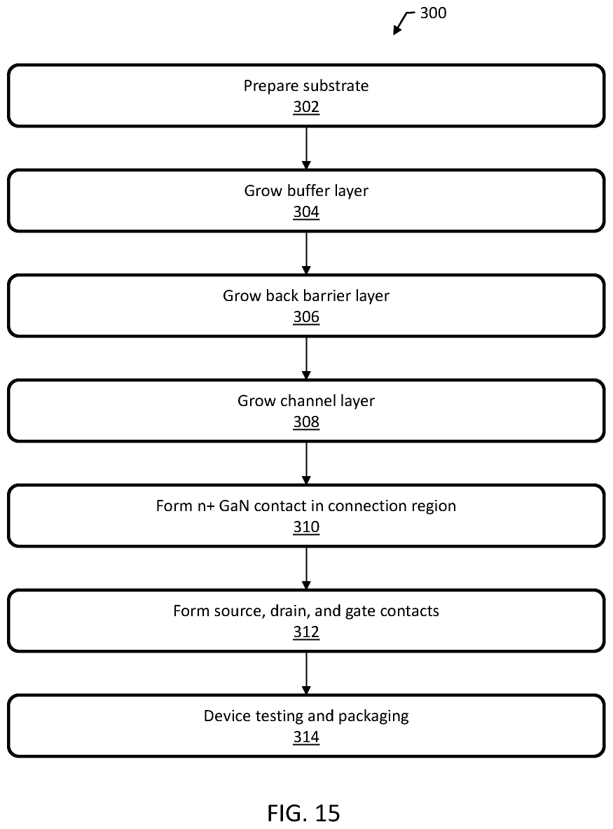

FIG. 14 is a cross-sectional view of the transistor 200 in an example where the n+ GaN contact 220 extends through the barrier layer 208 and into the channel layer 206. In this example, the transistor 200 also includes an optional ohmic metal 224 on top of the n+ GaN contact 220 in the connection region. In this case, the 2 DEG channel 210 is broken, but a sufficiently low-resistance n+ GaN can reduce the resistance penalty. The n+ GaN contact 220 includes overhang 226 extending towards the first gate 216 and the second gate 218

FIG. 15 is a flow diagram of an example method 300 for fabricating a dual gate HEMT with an n+ GaN contact, e.g., the transistor 100 shown in FIGS. 1-12.

The method 300 includes preparing a substrate, which can be, e.g., a sapphire wafer or silicon carbide substrate (302). The substrate is cleaned and prepared for epitaxial growth.

The method 300 includes growing a buffer layer (304). A thin buffer layer is grown on the substrate, e.g., to reduce the lattice mismatch between the substrate and the GaN layer. This layer is typically made of AlGaN or GaN and is grown by, e.g., metalorganic chemical vapor deposition (MOCVD) or molecular beam epitaxy (MBE). It may be doped with impurities such as iron or carbon to render it insulating in some regions, and it may be doped with Si or other electron donor impurities to balance charge elsewhere in the structure.

The method 300 includes growing a back barrier layer (306). A back barrier layer is grown on the buffer layer, e.g., to prevent electron leakage and increase the breakdown voltage of the device. This layer can be made of, e.g., AlGaN and can be grown by, e.g., MOCVD or MBE. This layer may, over a portion of its thickness, be doped with Si or other impurities.

The method 300 includes growing a channel layer (308). A GaN channel layer is grown on top of the back barrier layer. The channel layer can be grown by, e.g., MOCVD or MBE.

The method 300 includes growing an n+ GaN contact in a connection region between the first and second gates (310). The n+ GaN contact can be formed, e.g., on a surface of the channel layer or from within an etched recess within the channel layer.

The method 300 includes forming source, drain, and first and second gate contacts (312). The source and drain n+regions can be formed at the same time as the n+ GaN contact in the connection region. Metal contacts are deposited to form the source and drain electrodes. These contacts are typically made of a combination of metals such as Ti, Al, Ni, Au, and can be patterned using photolithography and liftoff or etching. To form the gate contacts, a metal layer (e.g., Ti, Cr, Ru, Pt, or Pd) can be deposited, e.g., on top of a thin insulating layer. Photolithography and/or etching can be used to expose the channel region where the gates are deposited.

In some examples, the method 300 includes forming one or more etch stop layers. The etch stop layers can be used, e.g., to define recess depths for the gate contacts and/or the access regions in the channel layer.

The method 300 includes testing and packaging the transistor (314). The completed device is tested to ensure that it meets the desired specifications for electrical performance. Once testing is complete, the device is packaged for use in a specific application.

Various semiconductor devices, along with methods of forming semiconductor devices, have been described above. However, it should be understood that they have been presented by way of example only, and not limitation. Where methods and steps described above indicate certain events occurring in certain order, those of ordinary skill in the art would recognize that the ordering of certain steps may be modified and such modifications are in accordance with the variations of the disclosure. The implementations have been particularly shown and described, but it will be understood that various changes in form and details may be made. Accordingly, other implementations are within the scope of the following claims.

1. A semiconductor device comprising:
a III-N backbarrier layer;
a III-N channel layer over the III-N backbarrier layer;
a 2 DEG channel in the III-N channel layer;
a source contact coupled to the III-N channel layer;
a drain contact coupled to the III-N channel layer and spaced apart from the source contact along a length of the semiconductor device;
between the source contact and the drain contact, a first gate contact and a second gate contact coupled to the III-N channel layer;
an n+ GaN contact coupled to the III-N channel layer in a connection region between the first gate contact and the second gate contact.

2. The semiconductor device of claim 1, wherein one or more of the n+ GaN contact, the III-N channel layer, and the III-N backbarrier layer comprises N-polar GaN.

3. The semiconductor device of claim 1, comprising an ohmic metal on top of the n+ GaN contact in the connection region.

4. The semiconductor device of claim 1, wherein the first gate contact and the second gate contact are recessed to different depths in the III-N channel layer.

5. The semiconductor device of claim 1, wherein the first gate contact is recessed to a first depth, the second gate contact is recessed to a second depth, and the first depth is greater than the second depth.

6. The semiconductor device of claim 1, wherein the second gate contact has a length greater than a length of the first gate contact.

7. The semiconductor device of claim 5, wherein a first access region between the source contact and the n+ GaN contact is recessed to a first access region depth, a second access region between the drain contact and the n+ GaN contact is recessed to a second access region depth, and the first access region depth is greater than the second access region depth.

8. The semiconductor device of claim 1, comprising one or more etch stop layers.

9. The semiconductor device of claim 1, comprising first and second etch stop layers, wherein the first gate contact is recessed to the first etch stop layer and the second gate contact is recessed to the second etch stop layer.

10. The semiconductor device of claim 1, comprising a first etch stop layer, wherein the first gate contact is recessed through and past the etch stop layer.

11. The semiconductor device of claim 1, comprising a first etch stop layer, wherein a first access region between the source contact and the n+ GaN contact is recessed to the first etch stop layer and the second gate is recessed to the etch stop layer.

12. The semiconductor device of claim 1, wherein the n+ GaN contact extends from an etched region of the III-N channel.

13. The semiconductor device of claim 1, wherein the n+ GaN contact extends from a surface of the III-N channel.

14. The semiconductor device of claim 1, wherein the first gate contact has a first gate width, the second gate contact has a second gate width, and the second gate width is wider than the first gate width.

15. The semiconductor device of claim 1, wherein the first gate contact comprises a plurality of non-conducting regions along a width of the first gate contact, wherein the non-conducting regions alternate with a plurality of conducting regions.

16. A semiconductor device comprising:
a III-N channel layer;
a III-N barrier layer over the III-N channel layer;
a 2 DEG channel in the III-N channel layer;
a source contact coupled to the III-N channel layer;
a drain contact coupled to the III-N channel layer and spaced apart from the source contact along a width of the semiconductor device;
between the source contact and the drain contact, a first gate contact above the III-N barrier layer and a second gate contact above the III-N barrier layer;
an n+ GaN contact coupled to the III-N barrier layer in a connection region between the first gate contact and the second gate contact, wherein the n+ GaN contact comprises Ga-polar GaN.

17. The semiconductor device of claim 16, wherein one or both of the source and drain contacts comprises an overhang extending over a surface of the III-N barrier layer.

18. The semiconductor device of claim 16, wherein the n+ GaN contact extends through the III-N barrier layer and into the III-N channel layer.

19. The semiconductor device of claim 18, comprising an ohmic metal on top of the n+ GaN contact in the connection region.

20. A method of fabricating a semiconductor device, the method comprising:
forming a III-N channel layer over a III-N backbarrier layer, thereby inducing a 2 DEG channel in the III-N channel layer;
forming source and drain contacts coupled to the III-N channel layer, wherein the source and drain contacts are spaced apart along a length of the semiconductor device;
forming an n+ GaN contact coupled to the III-N channel layer in a connection region; and
forming first and second gate contacts coupled to the III-N channel layer, wherein the first and second gate contacts are between the source and drain contacts, and wherein the n+ GaN contact is between the first gate contact and the second gate contact.
